(19) United States
(12) Patent Application Publication
(10) Pub. No.: US 2009/0221252 A1
(43) Pub. Date: Sep. 3, 2009

(54) LOW COMPLEXITY AGC FOR MB-OFDM

(75) Inventors: Henry Chun Cheung, Hong Kong (CN); Vincent Kin Nang Lau, Hong Kong (CN); Roger Shu Kwan Cheng, Hong Kong (CN); Wai Ho Mow, Hong Kong (CN); Ross David Murch, Hong Kong (CN)

Correspondence Address: TUROCY & WATSON, LLP, 127 Public Square, 57th Floor, Key Tower, CLEVELAND, OH, 44114, US

(73) Assignee: THE HONG KONG UNIVERSITY OF SCIENCE AND TECHNOLOGY, Hong Kong (CN)

(21) Appl. No.: 12/039,898

(22) Filed: Feb. 29, 2008

(51) Int. Cl. H04B 1/06; H03G 3/00

(52) U.S. Cl. 455/234.1; 330/278

(57) ABSTRACT

System and methodologies for amplifier gain control in a communication system are provided herein. By leveraging similarities between the distribution of received signal samples in an MB-OFDM system and a Gaussian distribution, various algorithms described herein can be utilized to perform fast and low-complexity amplifier gain tuning. Received signal strength indication information corresponding to analog signal samples and/or digital signal samples obtained from an analog to digital converter are analyzed to obtain a signal energy distribution. The obtained signal energy distribution is then compared to a reference Gaussian distribution to adaptively tune an associated amplifier gain.

### TECHNICAL FIELD

The present disclosure relates generally to wireless communications systems, and more particularly to techniques for amplifier gain control in a wireless communication system.

### BACKGROUND

As wireless communication technology advances and the demand for wireless communication applications increases, various advances have been made to increase the capacity and reliability of wireless communication systems. For example, automatic gain control (AGC) can be implemented in devices operating in a wireless communication network to control the amplitude of signals communicated over the network, thereby improving the quality of such signals.

Traditionally, AGC is implemented in a wireless communication system using a complex control theoretic feedback loop such as a proportional-integral-derivative (PID) controller. However, in many wireless communication systems, such as Ultra Wideband (UWB) wireless systems employing Multi-Band Orthogonal Frequency Division Multiplexing (MB-OFDM), this conventional technique for AGC is prohibitively complex and results in a decrease in overall system performance. Further, for applications such as Wireless Personal Area Network (WPAN) piconets, the inefficiencies of traditional AGC techniques can be magnified by the presence of simultaneously operating piconets (SOP) and/or other similar factors. Accordingly, there exists a need for efficient techniques for amplifier gain control in a communication system.

### SUMMARY

The following presents a simplified summary of the claimed subject matter in order to provide a basic understanding of some aspects of the claimed subject matter. This summary is not an extensive overview of the claimed subject matter. It is intended to neither identify key or critical elements of the claimed subject matter nor delineate the scope of the claimed subject matter. Its sole purpose is to present some concepts of the claimed subject matter in a simplified form as a prelude to the more detailed description that is presented later.

The present disclosure provides systems and methodologies for amplifier gain control in a wireless communication system. In accordance with one aspect described herein, similarities between the distribution of received signal samples in an MB-OFDM system and a Gaussian distribution are leveraged to perform fast and low-complexity variable gain amplifier (VGA) gain tuning. Based on the standard deviation of an approximated Gaussian distribution for a wireless communication system, two low-complexity AGC algorithms are provided herein. The first such algorithm utilizes a received signal strength indication (RSSI) when available to facilitate VGA tuning, while the second such algorithm can operate without RSSI and can additionally account for the existence of simultaneously operating piconets. Both algorithms allow a VGA gain to be adaptively tuned such that a stable VGA gain is reached within one OFDM symbol in a MB-OFDM system.

To the accomplishment of the foregoing and related ends, certain illustrative aspects of the claimed subject matter are described herein in connection with the following description and the annexed drawings. These aspects are indicative, however, of but a few of the various ways in which the principles of the claimed subject matter can be employed. The claimed subject matter is intended to include all such aspects and their equivalents. Other advantages and novel features of the claimed subject matter can become apparent from the following detailed description when considered in conjunction with the drawings.

### BRIEF DESCRIPTION OF THE DRAWINGS

FIG. 1 is a high-level block diagram of a wireless communication system in accordance with various aspects.

FIG. 2 is a block diagram of an example wireless station in accordance with various aspects.

FIG. 3 illustrates signal amplitude distributions for an example wireless communication system in accordance with various aspects.

FIGS. 4-5 are state diagrams that illustrate respective example techniques for amplifier gain control in accordance with various aspects.

FIGS. 6-8 are flowcharts of respective methods of adjusting a variable gain amplifier in accordance with various aspects.

FIG. 9 is a block diagram of an example operating environment in which various aspects described herein can function.

FIG. 10 illustrates an example wireless communication network in which various aspects described herein can be utilized.

FIG. 11 illustrates an overview of a wireless network environment suitable for service by various aspects described herein.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

As used in this application, the terms “component,” “system,” and the like are intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a server and the server can be a component. One or more components may reside within a process and/or thread of execution and a component may be localized on one computer and/or distributed between two or more computers. Also, the methods and apparatus of the claimed subject matter, or certain aspects or portions thereof, may take the form of program code (i.e., instructions) embodied in tangible media, such as floppy diskettes, CD-ROMs, hard drives, or any other machine-readable storage medium, wherein, when the program code is loaded into and executed by a machine, such as a computer, the machine becomes an apparatus for practicing the claimed subject matter. The components may communicate via local and/or remote processes such as in accordance with a signal having one or more data packets (e.g., data from one component interacting with another component in a local system, distributed system, and/or across a network such as the Internet with other systems via the signal).

Additionally, while the present disclosure generally relates to an Ultra-Wideband (UWB) wireless communication system utilizing Multi-Band Orthogonal Frequency Division Multiplexing (MB-OFDM), those skilled in the art will recognize that the claimed subject matter can be used and applied in any wired or wireless communication system that utilizes variable gain amplification. It is to be appreciated that the systems and/or methods described herein can be employed in any suitable wireless communication system and that all such systems are intended to fall within the scope of the hereto appended claims.

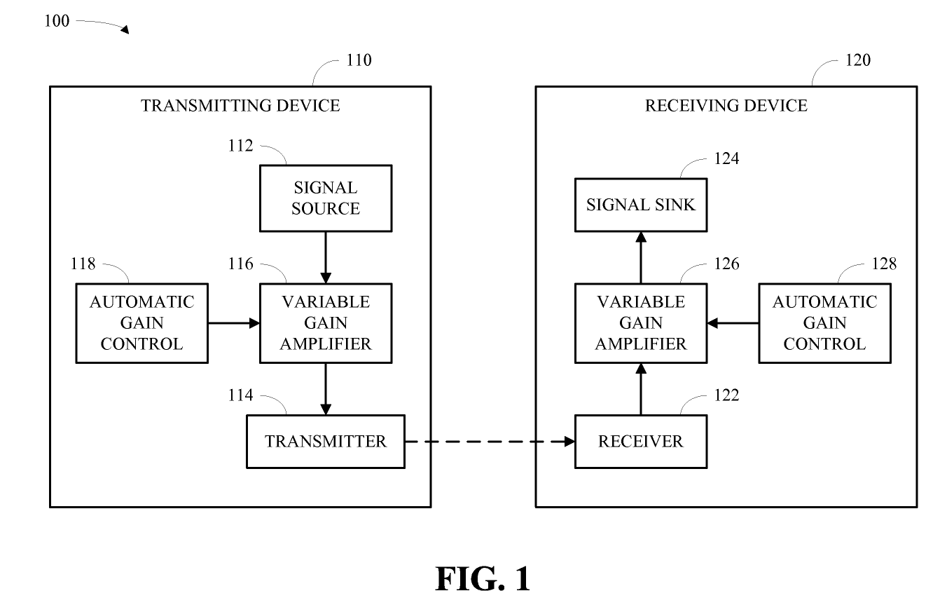

Referring to FIG. 1, a high-level block diagram of a wireless communication system 100 in accordance with various aspects presented herein is illustrated. In one example, system 100 includes one or more devices 110 and/or 120, which can communicate with each other over a wired and/or wireless communication link. Devices 110 and/or 120 in system 100 can be associated with one or more piconets, which in turn can be associated with one or more wireless personal area networks (WPANs) and/or other suitable wireless communication networks. While two devices 110 and 120 are illustrated in system 100, it should be appreciated that system 100 and/or piconet(s) associated therewith can include any number of devices 110 and/or 120.

In accordance with one aspect, a transmitting device 110 in system 100 can transmit data, control signaling (e.g., beacons), and/or other information to a receiving device 120 in system 100. While device 110 is labeled as a transmitting device and device 120 is labeled as a receiving device in system 100, it should be appreciated that devices 110 and/or 120 can be capable of both receiving and transmitting at one or more time intervals. For example, while not illustrated in system 100, a receiving device 120 in system 100 can additionally transmit information to a transmitting device 110 in system 100 at a common time interval as a transmission from the transmitting device 110 to the receiving device 120 or at a different time interval.

A communication within system 100 can be initiated, for example, by a transmitting device 110 in system 100 by generating or otherwise identifying information to be transmitted from a signal source 112. Upon identifying information to be transmitted, the transmitting device 110 can transmit the information via a transmitter 114. The information can then be received by a receiving device 120 via a receiver 122 and provided to a signal sink 124 associated with the receiving device 120. By way of specific, non-limiting example, the transmitting device 110 and the receiving device 120 can convey information according to MB-OFDM communication, wherein information is transmitted from the transmitting station 110 to the receiving station 120 over multiple (e.g., 3) frequency subbands. Frequency subbands utilized by stations 110 and/or 120 for communication of signals can be based on a time-frequency code and/or determined by other suitable means.

In accordance with another aspect, a transmitting device 110 and/or a receiving device 120 in system 100 can comprise respective variable gain amplifiers (VGAs) 116 and/or 126. In one example, VGAs 116 and/or 126 can be utilized to adjust the amplitude of signals communicated in system 100 to account for interference, channel conditions, and other factors that can affect the reliability of signals communicated in system 100. For example, a transmitting device 110 in system 100 can employ a VGA 116 to process signals from a signal source 112 prior to transmission by a transmitter 114, and a receiving device 120 can utilize a VGA 126 to process signals received at a receiver 122 prior to providing the received signals to a signal sink 124.

In one example, automatic gain control (AGC) modules 118 and/or 128 can be respectively employed by devices 110 and/or 120 to control gain factors used by corresponding VGAs 116 and/or 126. In accordance with one aspect, AGC modules 118 and/or 128 can be configured to leverage similarities between the distribution of received signal samples in system 100 and a Gaussian distribution to provide fast and low-complexity tuning functionality for associated VGAs 116 and/or 118. In one example, the VGA tuning functionality provided by AGC modules 118 and/or 128 can be made resilient to interference, channel noise, the presence of simultaneously operating piconets, and/or other factors to provide effective VGA gain tuning for WPANs and other similar network architectures. Examples of techniques that can be utilized by AGC modules 118 and/or 128 for the adjustment of corresponding VGAs 116 and/or 126 are described in more detail infra.

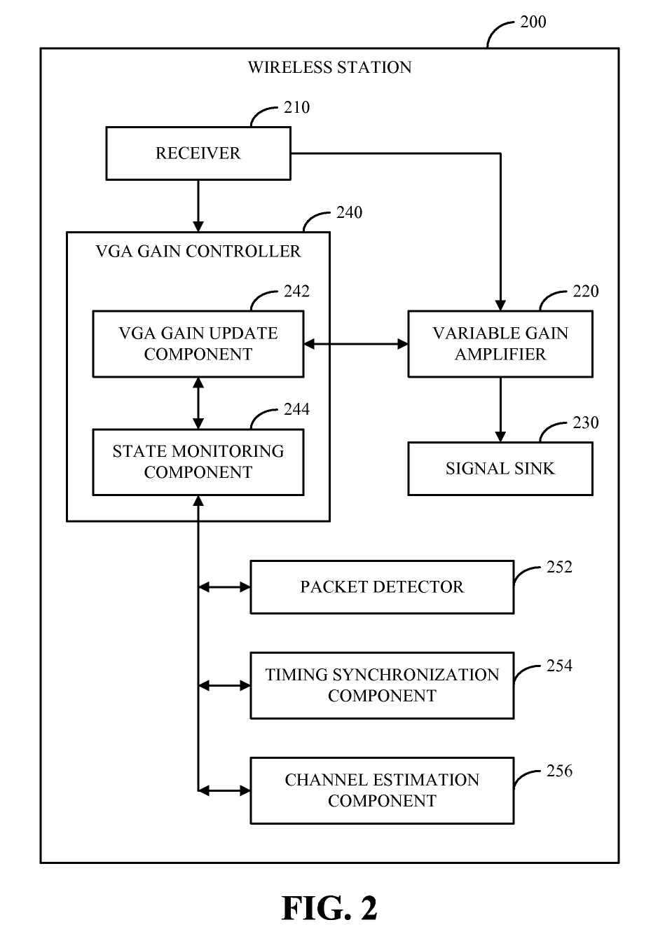

Turning to FIG. 2, a block diagram of an example wireless station 200 in accordance with various aspects is illustrated. In one example, station 200 can include a receiver 210, which can receive signals from one or more stations communicatively associated with station 200 (e.g., device 110 in system 100) and/or other entities in a wireless communication system. Although not illustrated in FIG. 2, station 200 can additionally include a transmitter for transmitting information to other entities in the wireless communication system. In accordance with one aspect, information received by the receiver 210 can be provided to a VGA 220, wherein an adjustable gain factor can be applied to compensate for interference, channel noise, and/or other factors to increase the quality of the received information. After processing by the VGA 220, the information can be provided to a signal sink 230.

In accordance with another aspect, station 200 can include a VGA gain controller 240, which can adjust a gain factor applied by the VGA 220 for signals provided to the VGA 220 by the receiver 210. Traditionally, VGA gain control is implemented using a proportional-integral-derivative (PID) controller or a similar complex control structure. However, in various types of communication environments, such as Ultra Wideband (UWB) wireless systems employing Multi-Band Orthogonal Frequency Division Multiplexing (MB-OFDM) and/or WPAN piconets, conventional VGA gain control techniques add unnecessary complexity to the operation of a device such as station 200, thereby reducing the effectiveness of the device and its associated communication network. In contrast, to reduce the complexity associated with controlling the gain of VGA 220, the VGA gain controller 240 at station 200 can approximate an amplitude distribution of signals received from the receiver 210 as a Gaussian distribution. Based on this approximation, the VGA gain controller can utilize one or more techniques for controlling the gain of the VGA 220 based on properties of Gaussian distributions.

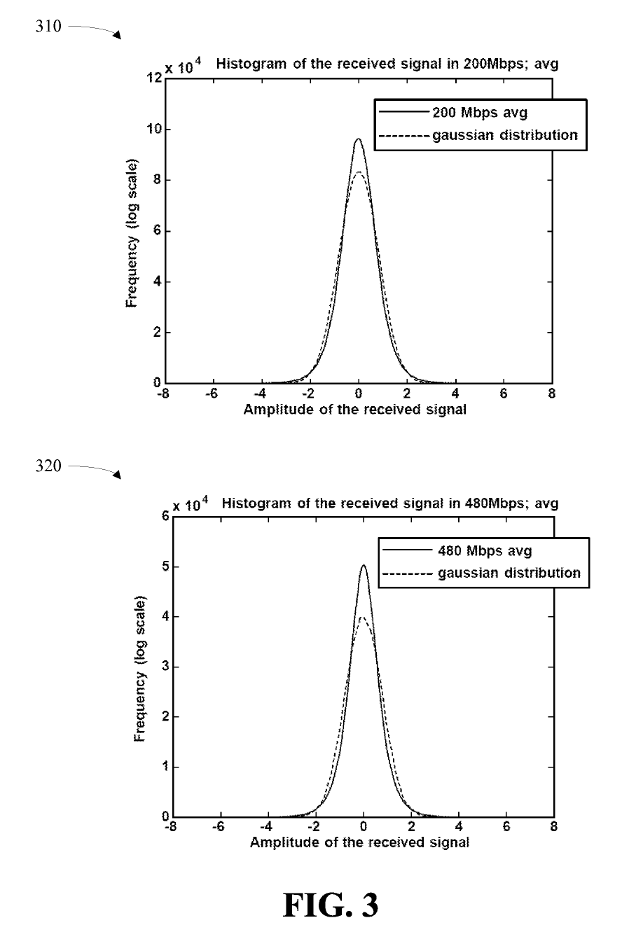

By way of non-limiting example, a VGA gain controller 240 associated with a wireless station 200 operating in a UWB wireless communication system can approximate a series received signals as a Gaussian distribution as illustrated by FIG. 3. FIG. 3 includes two graphs 310 and 320, which illustrate average signal sample in-phase amplitude distributions for an example UWB channel at rates of 200 Mbps and 480 Mbps, respectively. Graph 310 illustrates an amplitude distribution for a sample set of 1.7M signals at a SNR of 10 dB, while graph 320 illustrates an amplitude distribution for a sample set of 770 k signals at a SNR of 19 dB. To generate the distributions illustrated by graphs 310 and 320, the source bits were randomly generated. The dark lines in graphs 310 and 320 represent the actual measured amplitude distributions, while the light lines represent Gaussian amplitude distributions for the same respective numbers of signal samples used in the sample sets for graphs 310 and 320. The standard deviations of the Gaussian distributions in graphs 310 and 320 are 0.8083 and 0.7681, respectively. As can be observed from graphs 310 and 320, the respective Gaussian distributions closely approximate the actual measured amplitude distributions in both cases. Thus, Gaussian distribution approximations for received signals, such as those illustrated in FIG. 3, can be utilized by the VGA gain controller 240 at station 200 to tune the gain of the VGA 220.

In accordance with one aspect, the VGA gain controller 240 at station 200 can include a VGA gain update component 242 and a state monitoring component 244, which can operate alone or in combination with each other and/or other components of station 200 to adjust the gain of the VGA 220. In one example, the VGA gain update component 242 can analyze data such as the current gain of the VGA 220, quantized digital samples obtained from an analog to digital converter (ADC) embedded at the VGA 220, signal quality indicators (e.g., RSSI) from the receiver 210, information regarding interference, channel state, and/or other aspects of a communication channel utilized by station 200, a current operating state identified by the state monitoring component 244, and/or other suitable data. Based on this analysis, the VGA gain update component 242 can control a gain factor utilized by the VGA 220. In another example, the state monitoring component 244 can obtain information relating to a current operating state of station 200 from components of station 200 such as a packet detector 252, a timing synchronization component 254, a channel estimation component 256, and/or another suitable component. Based on this information, the state monitoring component 244 can identify the current operating state of 244, which can then be utilized to control the VGA gain update component 242 and/or other elements of the VGA gain controller 240. Various techniques that can be utilized by the VGA gain update component 242 and/or the state monitoring component 244 for adjusting the gain of the VGA 220 are discussed in more detail infra.

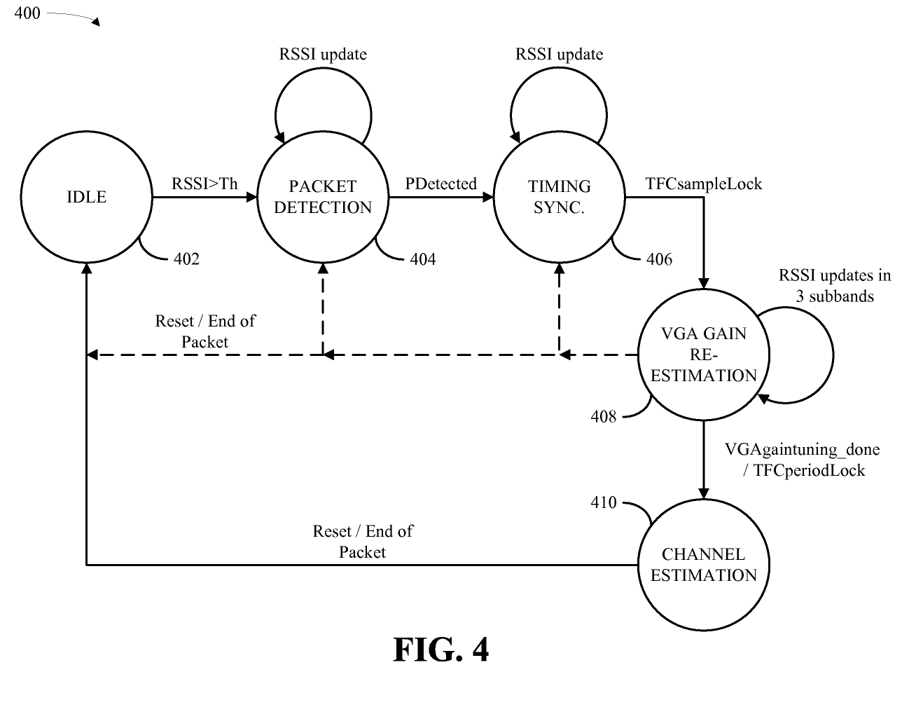

Turning now to FIG. 4, a state diagram 400 is provided that illustrates an example technique that can be utilized by the VGA gain controller 240 for controlling the gain of the VGA 220 in accordance with various aspects. In one example, the technique illustrated by state diagram 400 can be utilized to control VGA gain at a device such as station 200 that does not operate in the presence of simultaneously operating piconets (SOP) and that operates in a wireless communication system where received signal strength indication (RSSI) information is available. In accordance with one aspect, without the adverse effect of SOP, RSSI information corresponding to signals received at the receiver 210 can be utilized to adjust the gain of the VGA 220 as follows.

In accordance with one aspect, the technique illustrated by state diagram 400 can be initialized by approximating the amplitude of received signals at station 200 as a Gaussian distribution. Further, based on the standard deviations of the Gaussian distributions noted with respect to graphs 310 and 320, the three-sigma value of the Gaussian distribution approximation utilized by station 200, which represents the amplitude range into which 99% of all received signals are expected to fall, can be set as the ADC saturation limits of the VGA 220.

After initialization of the VGA 220, the VGA gain controller 240 can inter an idle state 402. In one example, the idle state 402 acts as a “sleep mode” wherein a default initial constant VGA gain is applied based on a predetermined worst case signal-to-noise ratio (SNR). In the idle state 402, the VGA gain controller can receive RSSI information updates from the receiver 210 and/or another appropriate source. If the VGA gain controller 240 detects that an RSSI update indicates an RSSI value that is above a predetermined threshold, the VGA gain controller 240 can transition to a packet detection state 404. In the packet detection state 404, the VGA gain controller 240 can continuously tune the gain of the VGA 220 based on successive RSSI updates until a PDetected control signal is fed back to the VGA gain controller 240 (e.g., by the packet detector 252).

Once the VGA gain controller 240 receives a PDetected control signal, it can enter a timing synchronization state 406, wherein the VGA gain controller 240 continues to tune the gain of the VGA 220 based on received RSSI information until a TFCsampleLock control signal is provided to the VGA gain controller 240 (e.g., by the timing synchronization component 254). After receiving the TFCsampleLock control signal, the VGA gain controller 240 enters a VGA gain re-estimation state 408, wherein VGA gains for all subbands used for communication by station 200 are re-estimated. Upon re-estimation of the VGA gains for all subbands, the smallest estimated VGA gain among the subbands can be selected as the VGA gain for all subbands. In the example illustrated by state diagram 400, VGA gain re-estimation can be performed for three subbands; however, it should be appreciated that the VGA gain re-estimation can be carried out for any appropriate number of subbands.

From the VGA gain re-estimation state 408, the VGA gain controller 240 can enter a channel estimation state 410 after a VGAgaintuning_done control signal (indicating that the smallest stabilized VGA gain among the subbands has been found), a TFCperiodLock control signal (indicating that the end of a predetermined number of preambles, e.g., 24 preambles, has been reached), and/or another appropriate control signal is received. In one example, once the VGA gain controller 240 reaches the channel estimation state 410, VGA gain tuning completes and the VGA gain controller 240 ceases tuning the gain of the VGA 220. In another example, the VGA gain controller 240 can return to the idle state 402 from any other state 404-410 when either a reset signal or an EndofPacket control signal is received.

In accordance with one aspect, VGA gain can be adjusted at the packet detection state 404, the timing synchronization state 406, and/or the VGA gain re-estimation state 408 based on RSSI information as follows. In one example, it can be assumed that RSSI provides average energy values for respective received signals, which can be expressed as E[I²]+E[Q²], where I and Q respectively represent in-phase and quadrature components. If it is further assumed that the E[I²] and E[Q²] values are equal, actual three-sigma values for respective in-phase and quadrature amplitudes can be obtained from the RSSI as follows:

$$actual three \text{-} sigma = 3 \cdot \sqrt{\frac{E [ {I}^{2} ] - E [ {Q}^{2} ]}{2}} . \qquad ( 1 )$$

Based on the actual three-sigma values obtained by Equation (1), the VGA gain can then be updated as follows:

updated VGA gain=predefined three-sigma/actual three-sigma, (2)

where the predefined three-sigma is the three-sigma value obtained for a Gaussian distribution approximation of the received signals as illustrated by FIG. 3 and is set as the ADC saturation limits.

By way of further example, an algorithm that can be employed by VGA gain controller 240 to adjust the gain of the VGA 220 based on RSSI information is detailed using pseudo-code in Table 1 below:

TABLE 1
Pseudo-code for an example RSSI-driven VGA gain control algorithm.

| | |
|---|---|
| 1 | VGA_gain = worst_SNR_VGA_gain |
| 2 | For every 10 input analog signal samples: |

| | |
|---|---|
| 3 | calculate average input energy from RSSI |
| 4 | $find actual three \text{-} sigma by 3 \cdot \sqrt{\frac{average input energy}{2}}$ |
| 5 | update VGA_gain |

| | |
|---|---|
| 6 | end |

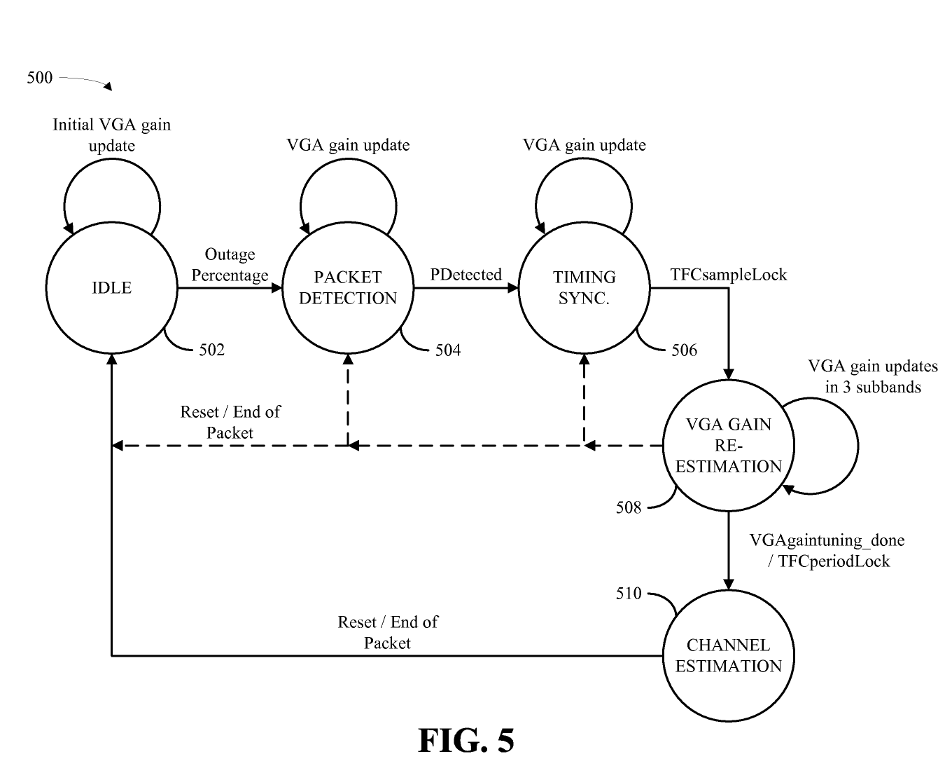

Referring to FIG. 5, an additional state diagram 500 is provided that illustrates another example technique that can be utilized by the VGA gain controller 240 for controlling the gain of the VGA 220 in accordance with various aspects. In one example, the technique illustrated by state diagram 500 can be utilized to control VGA gain at a device such as station 200 that operates in the presence of simultaneously operating piconets (SOP) and/or at a device for which RSSI information is not available. It should be appreciated, however, that the techniques illustrated by state diagrams 400 and 500 can be utilized by any suitable device operating in a wireless communication system, either separately or in combination with each other and/or other VGA gain control techniques.

In accordance with one aspect, the technique illustrated by state diagram 500 can be initialized by approximating the amplitude of received signals at station 200 as a Gaussian distribution. Further, based on the standard deviations of the Gaussian distributions noted with respect to graphs 310 and 320, the three-sigma value of the Gaussian distribution approximation utilized by station 200, which represents the amplitude range into which 99% of all received signals are expected to fall, can be set as the analog to digital converter (ADC) saturation limits of the VGA 220. By considering the percentage of ADC output samples that fall outside the saturation range and/or that concentrate in the center of the ADC quantization levels, the gain of the VGA 220 can then be adaptively tuned as follows by estimating the actual standard deviation (e.g., sigma) of the ADC samples at the VGA 220.

In one example, the VGA gain controller 240 can inter an idle state 502 after initialization. In one example, the idle state 502 acts as a “sleep mode” having a default initial constant VGA gain based on a predetermined worst case SNR. In the idle state 502, the VGA gain controller can continuously update the gain of the VGA 220 by tracking the noise and interference power of signals received by the receiver 210. If the VGA gain controller 240 detects that at least a predetermined percentage of received signal samples are out of the dynamic range of the ADC, the VGA gain controller 240 can transition to a packet detection state 504. In the packet detection state 504, the VGA gain controller 240 can continuously tune the gain of the VGA 220 based on an adaptive adjustment algorithm until a PDetected control signal is fed back to the VGA gain controller 240. Examples of adaptive adjustment algorithms that can be utilized by the VGA gain controller 240 are described in more detail infra.

Once the VGA gain controller 240 receives a PDetected control signal, the VGA gain controller 240 enters a timing synchronization state 506. In the timing synchronization state 506, the VGA gain controller 240 continues to tune the gain of the VGA 220 based on computed percentages of samples relative to the dynamic range of the ADC until a TFCsampleLock control signal is received. After receiving a TFCsampleLock control signal, the VGA gain controller 240 can enter a VGA gain re-estimation state 508, wherein VGA gains for all subbands used for communication by station 200 are re-estimated. Upon re-estimation of the VGA gains for all subbands, the smallest estimated VGA gain among the subbands can be selected as the VGA gain for all subbands. In the example illustrated by state diagram 500, VGA gain re-estimation can be performed for three subbands; however, it should be appreciated that VGA gain re-estimation can be carried out for any appropriate number of subbands.

From the VGA gain re-estimation state 508, the VGA gain controller 240 can enter a channel estimation state 510 after a VGAgaintuning_done control signal, a TFCperiodLock control signal, and/or another appropriate control signal is received in a similar manner to that described above with regard to state diagram 400. In one example, VGA gain tuning completes at the channel estimation state 510 and no further tuning of the VGA 220 is performed by the VGA gain controller 240. In accordance with one aspect, the VGA gain controller 240 can return to the idle state 502 from any other state 504-510 when either a reset signal or an EndofPacket control signal is received.

In accordance with an aspect, the initial VGA gain can be updated at the idle state 502 based on an existing environmental noise and interference level in order to prevent the timing synchronization process from having a high false alarm rate. By way of specific example, one or more of the following algorithms can be implemented to perform an initial VGA gain update.

In one example, by collecting received signal samples over a series of packets that includes a desired signal along with measurements of associated noise and interference powers, the long-term received signal variance can be calculated. The long-term received signal variance can represent, for example, the sum of the energy of a desired signal and associated noise and interference energy. Accordingly, by identifying and feeding back the desired signal energy via the timing synchronization process during cross-correlation, the desired signal energy can be eliminated from the long-term received signal variance to isolate the noise and interference energy. Based on the average noise and interference energy, the initial VGA gain can then be updated to prevent the noise and interference from being magnified to a large quantization level and consequently causing false detection in the timing synchronization process.

In another example, received signal samples can be collected over a series of packets to identify a long-term received signal variance in a similar manner to that described with regard to the previous example. If, in contrast to the previous example, the timing synchronization is not operable to feed back the desired signal energy, noise and interference energy can instead be obtained by observing idle transmission gaps between successive packets, which in one example are approximately 15 ms in length. In accordance with one aspect, the idle transmission gaps include only noise and interference energy; accordingly, the noise and interference energy can be estimated from the idle transmission gaps and used to update the initial VGA gain at the idle state 502.

In accordance with another aspect, VGA gain can be adjusted at the packet detection state 504, the timing synchronization state 506, and/or the VGA gain re-estimation state 508 as follows. From the observation that the in-phase amplitude distribution of received signals can be approximated as a Gaussian distribution, a three-sigma value, which represents a value for which 99% of received signals fall within the dynamic range of the ADC, can be utilized. Table 2 below illustrates the relationship between percentages of data that fall within the dynamic range of an ADC and corresponding standard deviations on a Gaussian distribution (e.g., multiples of sigma), which can be utilized by the VGA gain controller 240 for adjustment.

TABLE 2
Multiple of sigma vs. percentage of data within
dynamic range for a Gaussian distribution.

| Multiple of Sigma | Percent of Data |
|---|---|
| 0.2 | 15.85 |
| 0.4 | 31.08 |
| 0.6 | 45.15 |
| 0.8 | 57.63 |
| 1.0 | 68.27 |
| 1.2 | 76.99 |
| 1.4 | 83.85 |
| 1.6 | 89.04 |
| 1.8 | 92.81 |
| 2.0 | 95.45 |
| 2.5 | 98.76 |
| 3.0 | 99.73 |
| 4.0 | 99.94 |

While the three-sigma value obtained for a Gaussian distribution approximation of the received signals as illustrated by FIG. 3 can be pre-defined as the ADC saturation limits, the actual sigma value can be estimated from the percentile of data obtained in accordance with Table 2 above.

In accordance with one aspect, when data falls outside the dynamic range of the ADC and the percentage of data that are out of the range is obtained, the gain of the VGA 220 can be updated as follows:

updated VGA gain=actual three-sigma/predefined three-sigma. (3)

Further, if it is observed that the ADC output samples are concentrated in the center of the quantization levels of the ADC, a step-by-step quantization level checking process can be implemented to ensure that 99% of the output samples fall within the dynamic range. By way of example, an algorithm that can be employed by VGA gain controller 240 to adjust the gain of the VGA 220 based on ADC measurements is detailed using pseudo-code in Table 3 below:

TABLE 3
Pseudo-code for an example ADC-based VGA gain control algorithm.

| | |
|---|---|
| 1 | VGA_gain = worst_SNR_VGA_gain |
| 2 | For every 10 input analog signal samples: |
| 3 | Magnify the 10 samples with the VGA_gain |
| 4 | Quantize the 10 samples |
| 5 | Find the percentage of samples within the maximum quantization |
| | range (inner_percent) |
| 6 | If inner_percent < 99.73% |
| 7 | If 98.76% <= inner_percent < 99.73% |
| 8 | Updated_VGA_gain = 3/3 = 1 |
| 9 | Else if 95.45% <= inner_percent < 98.76% |
| 10 | Updated_VGA_gain = 2.5/3 |
| 11 | Else if 92.81% <= inner_percent < 95.45% |
| 12 | Updated_VGA_gain = 2.0/3 |
| 13 | Else if 89.04% <= inner_percent < 92.81% |
| 14 | Updated_VGA_gain = 1.8/3 |
| 15 | Else if 83.85% <= inner_percent < 89.04% |
| 16 | Updated_VGA_gain = 1.6/3 |
| 17 | Else if 76.99% <= inner_percent < 83.85% |
| 18 | Updated_VGA_gain = 1.4/3 |
| 19 | Else if 68.27% <= inner_percent < 76.99% |
| 20 | Updated_VGA_gain = 1.2/3 |
| 21 | Else if 57.63% <= inner_percent < 68.27% |
| 22 | Updated_VGA_gain = 1.0/3 |
| 23 | Else if 45.15% <= inner_percent < 57.63% |
| 24 | Updated_VGA_gain = 0.8/3 |
| 25 | Else if 31.08% <= inner_percent < 45.15% |
| 26 | Updated_VGA_gain = 0.6/3 |
| 27 | Else if 15.85% <= inner_percent < 31.08% |
| 28 | Updated_VGA_gain = 0.4/3 |
| 29 | Else if inner_percent < 15.85% |
| 30 | Updated_VGA_gain = 0.2/3 |
| 31 | end if |
| 32 | Else |
| 33 | For current_quantization level = |
| | current_quantization _level − 1 |
| 34 | Find the percentage of samples within the |
| | current_quantization_level (inner) |
| 35 | If inner < 99% |
| 36 | Updated_VGA_gain = VGA_gain * (max quantization |
| | level / (current_quantization_level + 1)) |
| 37 | end if |
| 38 | end |
| 39 | end if |
| 40 | end |

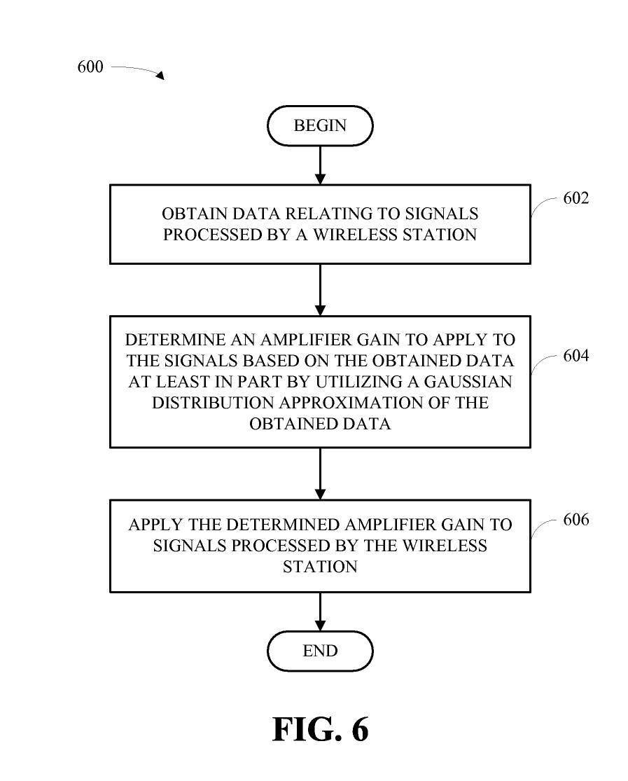

Referring now to FIGS. 6-8, methodologies that can be implemented in accordance with various aspects described herein are illustrated. While, for purposes of simplicity of explanation, the methodologies are shown and described as a series of blocks, it is to be understood and appreciated that the claimed subject matter is not limited by the order of the blocks, as some blocks may, in accordance with the claimed subject matter, occur in different orders and/or concurrently with other blocks from that shown and described herein. Moreover, not all illustrated blocks may be required to implement the methodologies in accordance with the claimed subject matter.

Furthermore, the claimed subject matter may be described in the general context of computer-executable instructions, such as program modules, executed by one or more components. Generally, program modules include routines, programs, objects, data structures, etc., that perform particular tasks or implement particular abstract data types. Typically the functionality of the program modules may be combined or distributed as desired in various embodiments. Furthermore, as will be appreciated various portions of the disclosed systems above and methods below may include or consist of artificial intelligence or knowledge or rule based components, sub-components, processes, means, methodologies, or mechanisms (e.g., support vector machines, neural networks, expert systems, Bayesian belief networks, fuzzy logic, data fusion engines, classifiers . . . ). Such components, inter alia, can automate certain mechanisms or processes performed thereby to make portions of the systems and methods more adaptive as well as efficient and intelligent.

Referring to FIG. 6, a method 600 of adjusting a variable gain amplifier (e.g., VGA 220 at station 200) is illustrated. At 602, data relating to signals processed by a wireless station (e.g., signals received by a receiver 210) are obtained. At 604, an amplifier gain to apply to the signals is determined (e.g., by a VGA gain controller 240) based on the data obtained at 602 at least in part by utilizing a Gaussian distribution approximation of the obtained data. At 606, the amplifier gain determined at 604 is applied to signals processed by the wireless station.

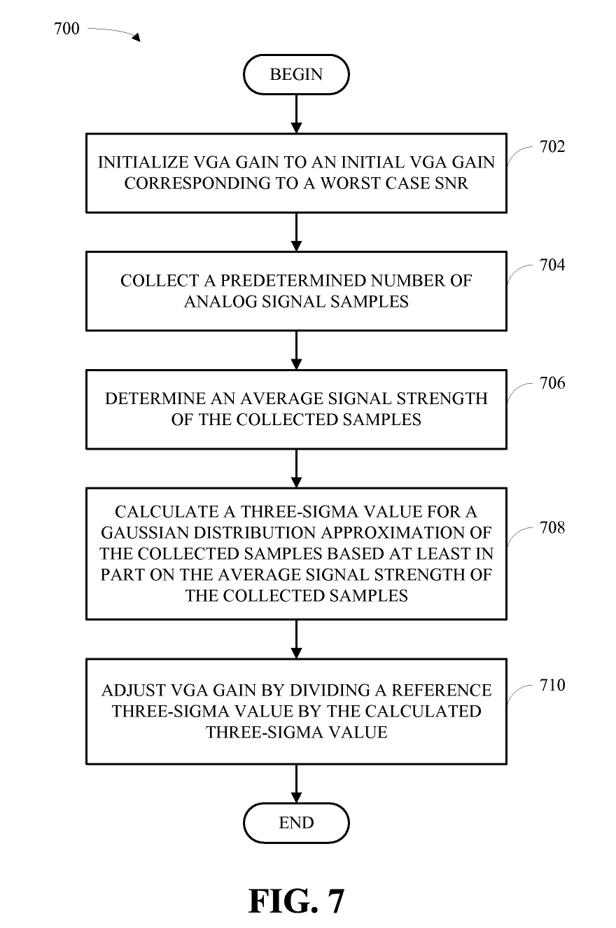

Turning now to FIG. 7, a flowchart of a method 700 of utilizing signal strength indications to adjust an amplifier gain is provided. At 702, the gain of a VGA is initialized to an initial VGA gain corresponding to a worst case signal-to-noise ratio (e.g., worst_SNR_VGA_gain). At 704, a predetermined number of analog signal samples (e.g., 10 samples) are collected. At 706, an average signal strength of the samples collected at 704 is determined. At 708, a three-sigma value for a Gaussian distribution approximation of the samples collected at 704 is calculated based at least in part on the average signal strength determined at 706. At 710, the VGA gain is adjusted by dividing a reference three-sigma value by the three-sigma value calculated at 708.

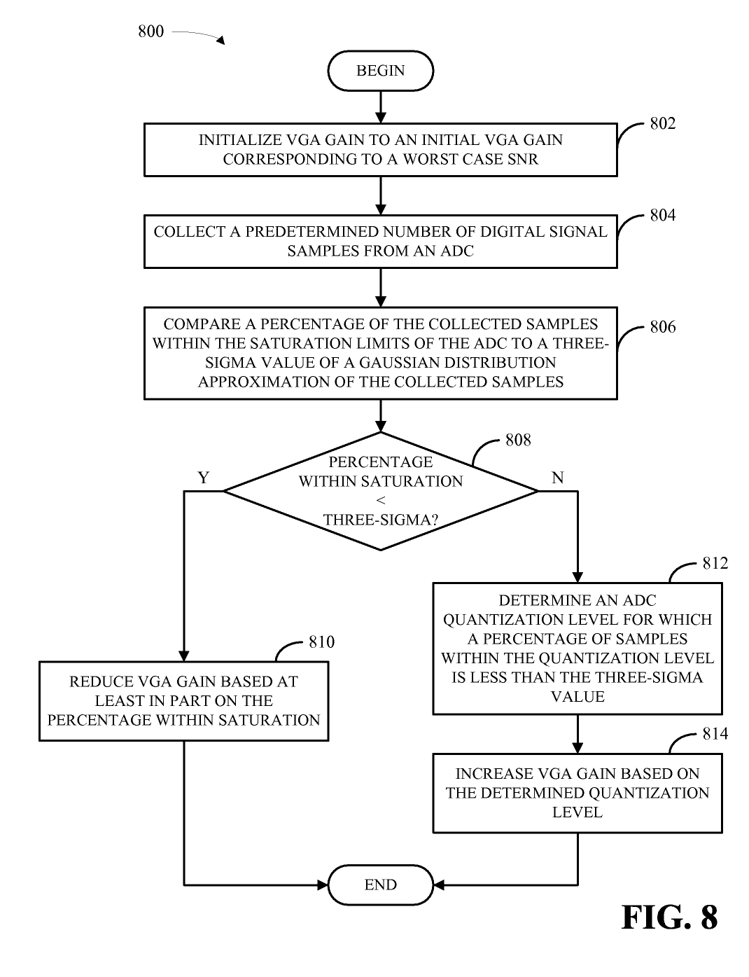

FIG. 8 illustrates a method 800 of tuning an amplifier based on ADC output measurements in accordance with various aspects. At 802, the gain of a VGA is initialized to an initial VGA gain factor corresponding to a worst case SNR (e.g., worst_SNR_VGA_gain). At 804, a predetermined number of digital signal samples (e.g., 10 samples) are collected from an ADC (e.g., following processing by a VGA 220). At 806, a percentage of the samples collected at 804 that are within the saturation limits of the ADC (e.g., inner_percent) is compared to a three-sigma value of a Gaussian distribution approximation of the collected samples.

At 808, it is determined whether the percentage of samples collected at 804 that are within the saturation limits of the ADC is less than the three-sigma value utilized at 806. If a positive determination is reached at 808, method 800 proceeds to 810, wherein the VGA gain is reduced (e.g., Updated_VGA_gain is applied) based at least in part on the percentage of samples collected at 804 that are within the saturation limits of the ADC. Otherwise, method 800 proceeds to 812, wherein an ADC quantization level for which a percentage of samples within the quantization level (e.g., inner) is less than the three sigma value is determined, and to 814, wherein the VGA gain is increased (e.g., Updated_VGA_gain is applied) based on the quantization level determined at 812.

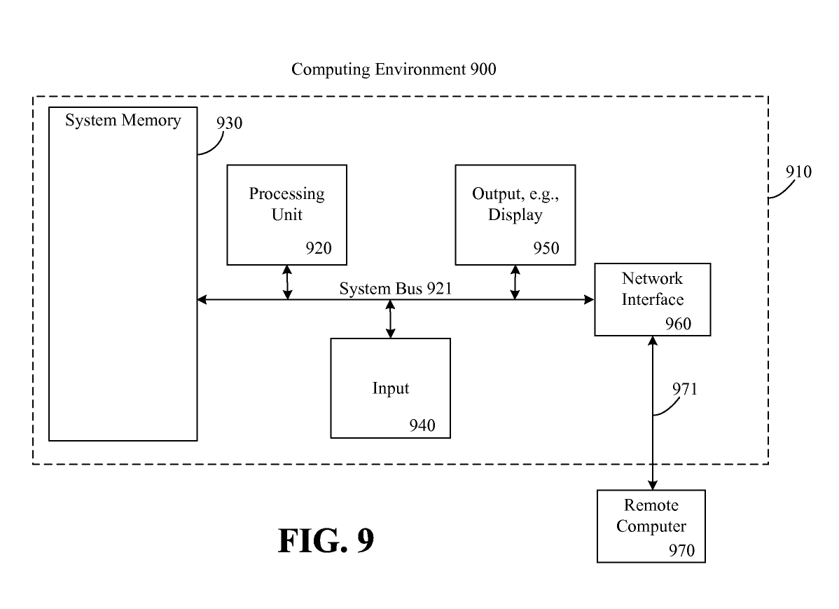

Turning to FIG. 9, an exemplary non-limiting computing system or operating environment in which various aspects described herein can be implemented is illustrated. One of ordinary skill in the art can appreciate that handheld, portable and other computing devices and computing objects of all kinds are contemplated for use in connection with the claimed subject matter, e.g., anywhere that a communications system may be desirably configured. Accordingly, the below general purpose remote computer described below in FIG. 9 is but one example of a computing system in which the claimed subject matter can be implemented.

Although not required, the claimed subject matter can partly be implemented via an operating system, for use by a developer of services for a device or object, and/or included within application software that operates in connection with one or more components of the claimed subject matter. Software may be described in the general context of computer-executable instructions, such as program modules, being executed by one or more computers, such as client workstations, servers or other devices. Those skilled in the art will appreciate that the claimed subject matter can also be practiced with other computer system configurations and protocols.

FIG. 9 thus illustrates an example of a suitable computing system environment 900 in which the claimed subject matter can be implemented, although as made clear above, the computing system environment 900 is only one example of a suitable computing environment for a media device and is not intended to suggest any limitation as to the scope of use or functionality of the claimed subject matter. Further, the computing environment 900 is not intended to suggest any dependency or requirement relating to the claimed subject matter and any one or combination of components illustrated in the example operating environment 900.

With reference to FIG. 9, an example of a remote device for implementing various aspects described herein includes a general purpose computing device in the form of a computer 910. Components of computer 910 can include, but are not limited to, a processing unit 920, a system memory 930, and a system bus 921 that couples various system components including the system memory to the processing unit 920. The system bus 921 can be any of several types of bus structures including a memory bus or memory controller, a peripheral bus, and a local bus using any of a variety of bus architectures.

Computer 910 can include a variety of computer readable media. Computer readable media can be any available media that can be accessed by computer 910. By way of example, and not limitation, computer readable media can comprise computer storage media and communication media. Computer storage media includes volatile and nonvolatile as well as removable and non-removable media implemented in any method or technology for storage of information such as computer readable instructions, data structures, program modules or other data. Computer storage media includes, but is not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other medium which can be used to store the desired information and which can be accessed by computer 910. Communication media can embody computer readable instructions, data structures, program modules or other data in a modulated data signal such as a carrier wave or other transport mechanism and can include any suitable information delivery media.

The system memory 930 can include computer storage media in the form of volatile and/or nonvolatile memory such as read only memory (ROM) and/or random access memory (RAM). A basic input/output system (BIOS), containing the basic routines that help to transfer information between elements within computer 910, such as during start-up, can be stored in memory 930. Memory 930 can also contain data and/or program modules that are immediately accessible to and/or presently being operated on by processing unit 920. By way of non-limiting example, memory 930 can also include an operating system, application programs, other program modules, and program data.

The computer 910 can also include other removable/non-removable, volatile/nonvolatile computer storage media. For example, computer 910 can include a hard disk drive that reads from or writes to non-removable, nonvolatile magnetic media, a magnetic disk drive that reads from or writes to a removable, nonvolatile magnetic disk, and/or an optical disk drive that reads from or writes to a removable, nonvolatile optical disk, such as a CD-ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM and the like. A hard disk drive can be connected to the system bus 921 through a non-removable memory interface such as an interface, and a magnetic disk drive or optical disk drive can be connected to the system bus 921 by a removable memory interface, such as an interface.

A user can enter commands and information into the computer 910 through input devices such as a keyboard or a pointing device such as a mouse, trackball, touch pad, and/or other pointing device. Other input devices can include a microphone, joystick, game pad, satellite dish, scanner, or the like. These and/or other input devices can be connected to the processing unit 920 through user input 940 and associated interface(s) that are coupled to the system bus 921, but can be connected by other interface and bus structures, such as a parallel port, game port or a universal serial bus (USB). A graphics subsystem can also be connected to the system bus 921. In addition, a monitor or other type of display device can be connected to the system bus 921 via an interface, such as output interface 950, which can in turn communicate with video memory. In addition to a monitor, computers can also include other peripheral output devices, such as speakers and/or a printer, which can also be connected through output interface 950.

The computer 910 can operate in a networked or distributed environment using logical connections to one or more other remote computers, such as remote computer 970, which can in turn have media capabilities different from device 910. The remote computer 970 can be a personal computer, a server, a router, a network PC, a peer device or other common network node, and/or any other remote media consumption or transmission device, and can include any or all of the elements described above relative to the computer 910. The logical connections depicted in FIG. 9 include a network 971, such local area network (LAN) or a wide area network (WAN), but can also include other networks/buses. Such networking environments are commonplace in homes, offices, enterprise-wide computer networks, intranets and the Internet.

When used in a LAN networking environment, the computer 910 is connected to the LAN 971 through a network interface or adapter. When used in a WAN networking environment, the computer 910 can include a communications component, such as a modem, or other means for establishing communications over the WAN, such as the Internet. A communications component, such as a modem, which can be internal or external, can be connected to the system bus 921 via the user input interface at input 940 and/or other appropriate mechanism. In a networked environment, program modules depicted relative to the computer 910, or portions thereof, can be stored in a remote memory storage device. It should be appreciated that the network connections shown and described are exemplary and other means of establishing a communications link between the computers can be used.

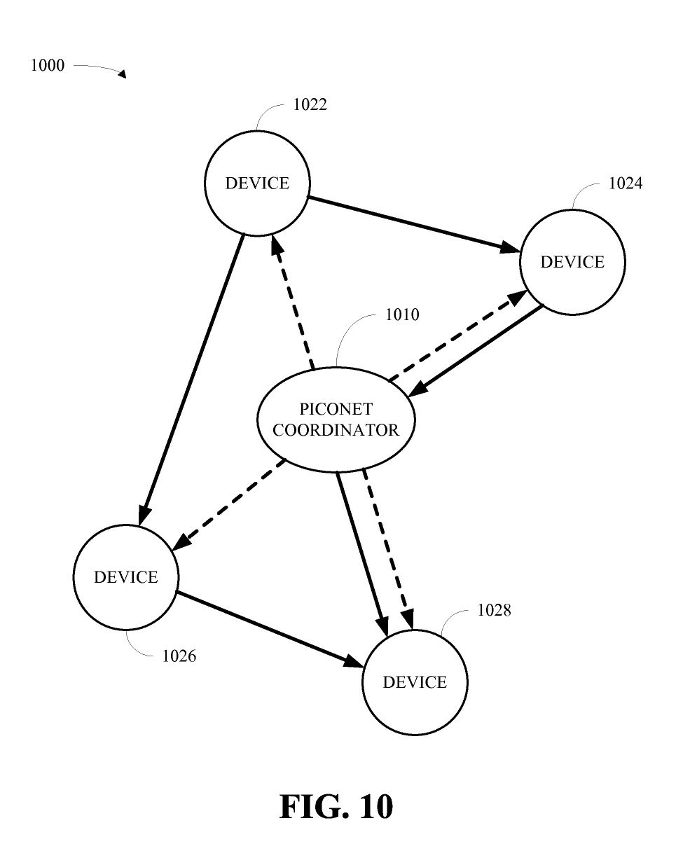

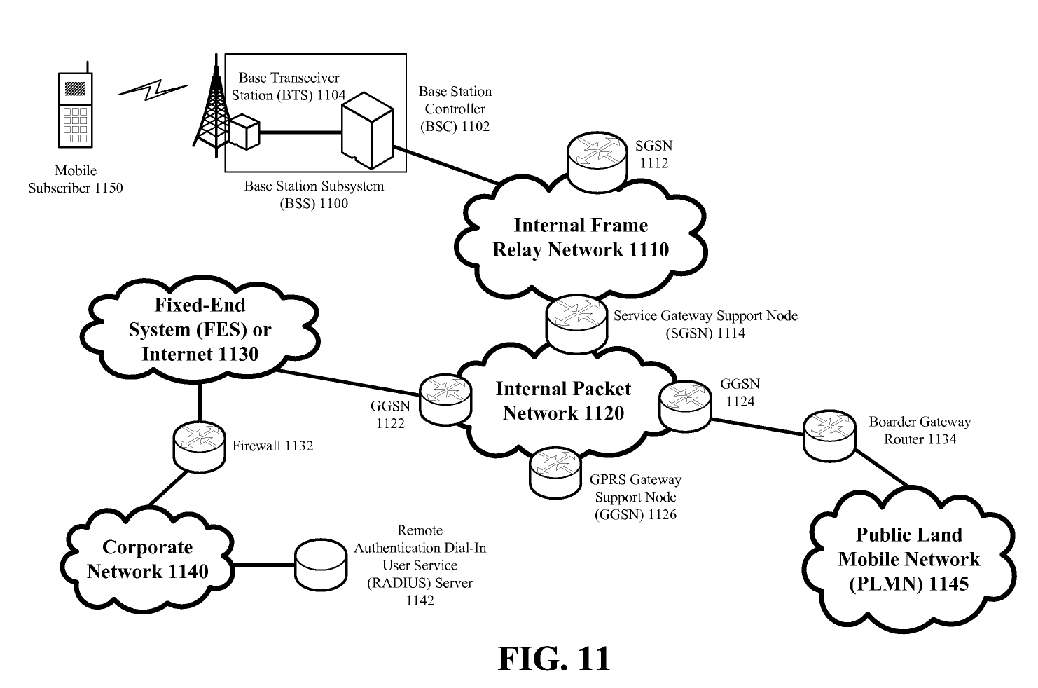

Turning now to FIGS. 10-11, an overview of network environments in which the claimed subject matter can be implemented is illustrated. The above-described systems and methodologies can be applied to any wireless communication network; however, the following description sets forth some exemplary, non-limiting operating environments for said systems and methodologies. The below-described operating environments should be considered non-exhaustive, and thus the below-described network architectures are merely examples of network architectures into which the claimed subject matter can be incorporated. It is to be appreciated that the claimed subject matter can be incorporated into any now existing or future alternative communication network architectures as well.

Referring first to FIG. 10, a wireless personal area network (WPAN) architecture 1000 based on the IEEE 802.15.3 high data rate WPAN standard is illustrated. Based on the IEEE 802.15.3 standard, the WPAN architecture 1000 can include one or more piconets. As used herein, a piconet is an ad hoc network of independent data devices 1010-1028 that can engage in peer-to-peer communication. FIG. 10 illustrates one such piconet. In one example, the range of a piconet is confined to a personal area of, for example, 10 to 50 meters, although a piconet can alternatively provide coverage for a larger or smaller coverage area.

In accordance with one aspect, a piconet can be established by a device 1010 that is capable of becoming a piconet coordinator (PNC). The device 1010 can establish the piconet by scanning a set of available communication channels (e.g., communication channels corresponding to time frequency codes in an MB-OFDM communication environment) for a channel having a least amount of interference that is not in use by neighboring piconets. Once such a communication channel is found, the device 1010 can become a PNC and begin transmitting control messaging in the form of beacons to allow other devices 1022-1028 to connect to the piconet. As illustrated in architecture 1000, beacons transmitted by PNC 1010 are shown by dotted lines.

Once a PNC 1010 establishes a piconet, one or more devices 1022-1028 can associate with the PNC 1010 based on beacons transmitted by the PNC 1010. In one example, beacons provided by a PNC 1010 can provide timing information, and a device 1022-1028 can perform one or more timing synchronization techniques based on received beacons as described supra while associating with the piconet coordinated by the PNC 1010. In addition, beacons transmitted by the PNC 1010 can also contain information relating to quality of service (QoS) parameters, time slots for transmission by devices 1022-1028 in the piconet, and/or other suitable information. After a device 1022-1028 has successfully associated with the piconet, it can then communicate in the piconet by transmitting data to the PNC 1010 and/or one or more other devices 1022-1028 in the piconet. As illustrated in architecture 1000, data transmissions are indicated by solid lines.

In accordance with one aspect, the PNC 1010 and devices 1022-1028 can additionally communicate using ultra-wideband (UWB) communication. When UWB is used, the PNC 1010 and/or devices 1022-1028 can communicate beacons and/or data using short-duration pulses that span a wide range of frequencies. In one example, transmissions made pursuant to UWB can occupy a spectrum of greater than 20% of a center frequency utilized by the network or a bandwidth of at least 500 MHz. Accordingly, UWB transmissions can be conducted using a very low power level (e.g., approximately 0.2 mW), which can allow UWB transmission to be conducted in common bands with other forms of communication without introducing significant interference levels. Because UWB operates at a low power level, it should be appreciated that UWB is typically confined to a small coverage area (e.g., approximately 10 to 100 meters), which can correspond to the coverage area of an associated piconet. However, by transmitting in short radio bursts that span a large frequency range, devices utilizing UWB can transmit significantly large amounts of data without requiring a large amount of transmit power. Further, because of the large bandwidth range and low transmit power used in UWB transmission, signals transmitted utilizing UWB can carry through obstacles that can reflect signals at lower bandwidth or higher power.

Turning now to FIG. 11, various aspects of the global system for mobile communication (GSM) are illustrated. GSM is one of the most widely utilized wireless access systems in today's fast growing communications systems. GSM provides circuit-switched data services to subscribers, such as mobile telephone or computer users. General Packet Radio Service (“GPRS”), which is an extension to GSM technology, introduces packet switching to GSM networks. GPRS uses a packet-based wireless communication technology to transfer high and low speed data and signaling in an efficient manner. GPRS optimizes the use of network and radio resources, thus enabling the cost effective and efficient use of GSM network resources for packet mode applications.

As one of ordinary skill in the art can appreciate, the exemplary GSM/GPRS environment and services described herein can also be extended to 3G services, such as Universal Mobile Telephone System (“UMTS”), Frequency Division Duplexing (“FDD”) and Time Division Duplexing (“TDD”), High Speed Packet Data Access (“HSPDA”), cdma2000 1x Evolution Data Optimized (“EVDO”), Code Division Multiple Access-2000 (“cdma2000 3x”), Time Division Synchronous Code Division Multiple Access (“TD-SCDMA”), Wideband Code Division Multiple Access (“WCDMA”), Enhanced Data GSM Environment (“EDGE”), International Mobile Telecommunications-2000 (“IMT-2000”), Digital Enhanced Cordless Telecommunications (“DECT”), etc., as well as to other network services that shall become available in time. In this regard, the timing synchronization techniques described herein may be applied independently of the method of data transport, and does not depend on any particular network architecture or underlying protocols.

FIG. 11 depicts an overall block diagram of an exemplary packet-based mobile cellular network environment, such as a GPRS network, in which the claimed subject matter can be practiced. Such an environment can include a plurality of Base Station Subsystems (BSS) 1100 (only one is shown), each of which can comprise a Base Station Controller (BSC) 1102 serving one or more Base Transceiver Stations (BTS) such as BTS 1104. BTS 1104 can serve as an access point where mobile subscriber devices 1150 become connected to the wireless network. In establishing a connection between a mobile subscriber device 1150 and a BTS 1104, one or more timing synchronization techniques as described supra can be utilized.

In one example, packet traffic originating from mobile subscriber 1150 is transported over the air interface to a BTS 1104, and from the BTS 1104 to the BSC 1102. Base station subsystems, such as BSS 1100, are a part of internal frame relay network 1110 that can include Service GPRS Support Nodes (“SGSN”) such as SGSN 1112 and 1114. Each SGSN is in turn connected to an internal packet network 1120 through which a SGSN 1112, 1114, etc., can route data packets to and from a plurality of gateway GPRS support nodes (GGSN) 1122, 1124, 1126, etc. As illustrated, SGSN 1114 and GGSNs 1122, 1124, and 1126 are part of internal packet network 1120. Gateway GPRS serving nodes 1122, 1124 and 1126 can provide an interface to external Internet Protocol (“IP”) networks such as Public Land Mobile Network (“PLMN”) 1145, corporate intranets 1140, or Fixed-End System (“FES”) or the public Internet 1130. As illustrated, subscriber corporate network 1140 can be connected to GGSN 1122 via firewall 1132; and PLMN 1145 can be connected to GGSN 1124 via boarder gateway router 1134. The Remote Authentication Dial-In User Service (“RADIUS”) server 1142 may also be used for caller authentication when a user of a mobile subscriber device 1150 calls corporate network 1140.

Generally, there can be four different cell sizes in a GSM network—macro, micro, pico, and umbrella cells. The coverage area of each cell is different in different environments. Macro cells can be regarded as cells where the base station antenna is installed in a mast or a building above average roof top level. Micro cells are cells whose antenna height is under average roof top level; they are typically used in urban areas. Pico cells are small cells having a diameter is a few dozen meters; they are mainly used indoors. On the other hand, umbrella cells are used to cover shadowed regions of smaller cells and fill in gaps in coverage between those cells.

The claimed subject matter has been described herein by way of examples. For the avoidance of doubt, the subject matter disclosed herein is not limited by such examples. In addition, any aspect or design described herein as “exemplary” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, for the avoidance of doubt, such terms are intended to be inclusive in a manner similar to the term “comprising” as an open transition word without precluding any additional or other elements.

Additionally, the disclosed subject matter can be implemented as a system, method, apparatus, or article of manufacture using standard programming and/or engineering techniques to produce software, firmware, hardware, or any combination thereof to control a computer or processor based device to implement aspects detailed herein. The terms “article of manufacture,” “computer program product” or similar terms, where used herein, are intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick). Additionally, it is known that a carrier wave can be employed to carry computer-readable electronic data such as those used in transmitting and receiving electronic mail or in accessing a network such as the Internet or a local area network (LAN).

The aforementioned systems have been described with respect to interaction between several components. It can be appreciated that such systems and components can include those components or specified sub-components, some of the specified components or sub-components, and/or additional components, according to various permutations and combinations of the foregoing. Sub-components can also be implemented as components communicatively coupled to other components rather than included within parent components, e.g., according to a hierarchical arrangement. Additionally, it should be noted that one or more components can be combined into a single component providing aggregate functionality or divided into several separate sub-components, and any one or more middle layers, such as a management layer, can be provided to communicatively couple to such sub-components in order to provide integrated functionality. Any components described herein can also interact with one or more other components not specifically described herein but generally known by those of skill in the art.

What is claimed is:

1. A system for processing signals in a wireless communication system, comprising:
an automatic gain control (AGC) module that determines an amplifier gain to apply to one or more signals at least in part by sampling the one or more signals to obtain corresponding signal samples and comparing an amplitude distribution of the signal samples to a reference Gaussian distribution; and
an amplifier that applies the determined amplifier gain to the one or more signals.

2. The system of claim 1, wherein the AGC module determines an average energy of the signal samples by identifying received signal strength indication (RSSI) information corresponding to the signal samples and determines the amplifier gain at least in part by comparing the average energy of the signal samples to a three-sigma value of the reference Gaussian distribution.

3. The system of claim 2, wherein the AGC module determines the average energy of the signal samples and determines the amplifier gain during one or more of a packet detection process, a timing synchronization process, or an amplifier gain re-estimation process.

4. The system of claim 3, wherein the AGC module determines the amplifier gain during an amplifier gain re-estimation process at least in part by determining respective amplifier gains for a plurality of frequency subbands, selecting an amplifier gain from the respective amplifier gains for the plurality of frequency subbands, and setting the respective amplifier gains for the frequency subbands to the selected amplifier gain.

5. The system of claim 1, wherein the signal samples are digital signal samples obtained from an analog to digital converter (ADC) associated with the amplifier and the AGC module determines a percentage of the signal samples that fall within a saturation range of the ADC, compares the determined percentage to a reference percentage associated with a three-sigma value of the reference Gaussian distribution, and adjusts the amplifier gain based on the comparison such that a resulting percentage of the signal samples that fall within the saturation range of the ADC more closely matches the percentage associated with the three-sigma value of the reference Gaussian distribution.

6. The system of claim 5, wherein the AGC module adjusts the amplifier gain during one or more of a packet detection process, a timing synchronization process, or an amplifier gain re-estimation process.

7. The system of claim 6, wherein the AGC module determines the amplifier gain during an amplifier gain re-estimation process at least in part by estimating respective amplifier gains for a plurality of frequency subbands, selecting an amplifier gain from the respective amplifier gains for the plurality of frequency subbands, and setting the respective amplifier gains for the frequency subbands to the selected amplifier gain.

8. The system of claim 5, wherein the AGC module determines an initial amplifier gain at least in part by obtaining an initial signal sample, subtracting a desired signal energy from the initial signal sample to obtain a combined noise and interference energy, and determining the initial amplifier gain based on the combined noise and interference energy.

9. The system of claim 5, wherein the AGC module determines an initial amplifier gain at least in part by detecting an idle transmission gap between a transmission of packets, obtaining a combined noise and interference energy from the idle transmission gap, and determining the initial amplifier gain based on the combined noise and interference energy.

10. A wireless personal area network (WPAN) piconet employing the system of claim 1.

11. A Multi-Band Orthogonal Frequency Division Multiplexing (MB-OFDM) Ultra Wideband (UWB) communication environment employing the system of claim 1.

12. A method of tuning a variable gain amplifier (VGA) in a wireless communication system, comprising:
obtaining one or more signal samples;
identifying one or more of an in-phase amplitude distribution or a quadrature amplitude distribution of the one or more signal samples;
comparing an identified amplitude distribution to a reference Gaussian amplitude distribution; and
adjusting a VGA gain factor based at least in part on the comparison.

13. The method of claim 12, wherein the identifying comprises receiving respective RSSI indications for the one or more signal samples and determining an average signal energy therefrom and the comparing comprises comparing the determined average signal energy to a three-sigma value of the reference Gaussian amplitude distribution.

14. The method of claim 12, wherein:
the obtaining comprises amplifying one or more signals using a VGA and obtaining one or more digital samples from the one or more signals from an ADC associated with the VGA after amplification;
the identifying comprises identifying a dynamic range of the ADC and determining a percentage of the digital samples that are within the dynamic range of the ADC;
the comparing comprises comparing the percentage of the digital samples that are within the dynamic range of the ADC to a three-sigma percentage for the reference Gaussian amplitude distribution; and
the adjusting comprises adjusting the VGA gain factor such that the percentage of the digital samples that are within the dynamic range of the ADC is equal or approximately equal to the three-sigma percentage for the reference Gaussian amplitude distribution.

15. The method of claim 14, further comprising:
sampling an initial signal;
identifying a desired signal energy level for the initial signal;
eliminating the desired signal energy level from the initial signal, thereby obtaining a remaining portion of the initial signal; and
initializing the VGA gain factor based at least in part on the remaining portion of the initial signal.

16. The method of claim 14, further comprising:
sampling a signal corresponding to an idle transmission;
obtaining an energy level of the sampled signal; and
initializing the VGA gain factor based at least in part on the energy level of the sampled signal.

17. The method of claim 12, wherein the identifying, comparing, and adjusting are performed during one or more of packet detection, timing synchronization, or VGA gain re-estimation.

18. The method of claim 12, wherein the adjusting comprises:
determining an adjusted VGA gain factor for a plurality of frequency subbands;
identifying a minimum adjusted VGA gain factor among the determined adjusted VGA gain factors; and
adjusting the VGA gain factor for the plurality of frequency subbands using the identified minimum adjusted VGA gain factor.

19. A computer-readable medium having stored thereon instructions operable to perform the method of claim 12.

20. A system that facilitates gain adjustment for a signal amplifier, comprising:
means for sampling one or more signals processed by an amplifier;
means for determining an energy distribution of the one or more signals;
means for comparing the determined energy distribution to a Gaussian distribution approximation of an expected energy distribution; and
means for adjusting a gain of the amplifier based at least in part on the comparison.
